(19) United States
(12) Patent Application Publication
(10) Pub. No.: US 2025/0081771 A1
(43) Pub. Date: Mar. 6, 2025

(54) DISPLAY DEVICE

(71) Applicant: Samsung Display Co., LTD., Yongin-si (KR)

(72) Inventors: SEUNG-JUN LEE, Yongin-si (KR); YONGSU LEE, Yongin-si (KR); JAEWOO LEE, Yongin-si (KR); SUNGEUN LEE, Yongin-si (KR)

(73) Assignee: Samsung Display Co., LTD., Yongin-si, Gyeonggi-do (KR)

(21) Appl. No.: 18/624,825

(22) Filed: Apr. 2, 2024

(30) Foreign Application Priority Data
Aug. 29, 2023 (KR) 10-2023-0113732

(51) Int. Cl. H10K 59/131; G09G 3/32

(52) U.S. Cl. CPC H10K 59/131; G09G 3/32; G09G 2300/0426; G09G 2300/0819; G09G 2300/0852

(57) ABSTRACT

A display device includes: an active layer disposed on a substrate, a first gate layer disposed on the active layer and including a first gate electrode, a second gate layer disposed on the first gate layer and including a capacitor electrode partially overlapping the first gate electrode, the capacitor electrode and the first gate electrode forming a first capacitor, a third gate layer disposed on the second gate layer and including a first power voltage line partially overlapping the capacitor electrode and receiving a first power voltage, the first power voltage line and the capacitor electrode forming a second capacitor, a data conductive layer disposed on the third gate layer, and an inorganic insulating layer disposed between the third gate layer and the data conductive layer, and covering the third gate layer.

### CROSS-REFERENCE TO RELATED APPLICATION(S)

This application claims priority to and benefits of Korean Patent Application No. 10-2023-0113732 under 35 U.S.C. § 119, filed on Aug. 29, 2023, in the Korean Intellectual Property Office (KIPO), the entire contents of which are incorporated herein by reference.

### BACKGROUND

### 1. Technical Field

Embodiments provide generally a display device. More particularly, embodiments relate to a display device which provides visual information.

### 2. Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

### SUMMARY

Embodiments provide a display device capable of implementing high resolution.

However, embodiments are not limited to those set forth herein. The above and other embodiments will become more apparent to one of ordinary skill in the art to which the disclosure pertains by referencing the detailed description of the disclosure given below.

A display device according to embodiments may include an active layer disposed on a substrate, a first gate layer disposed on the active layer and including a first gate electrode, a second gate layer disposed on the first gate layer and including a capacitor electrode partially overlapping the first gate electrode, the capacitor electrode and the first gate electrode forming a first capacitor, a third gate layer disposed on the second gate layer and including a first power voltage line partially overlapping the capacitor electrode and receiving a first power voltage, the first power voltage line and the capacitor electrode forming a second capacitor, a data conductive layer disposed on the third gate layer, and an inorganic insulating layer disposed between the third gate layer and the data conductive layer, and covering the third gate layer.

In an embodiment, the inorganic insulating layer may directly contact the third gate layer.

In an embodiment, the display device may further include a light emitting element disposed on the data conductive layer and including an anode electrode, an organic insulating layer disposed between the data conductive layer and the anode electrode, and a pixel defining layer disposed on the organic insulating layer and covering an edge portion of the anode electrode. Any organic insulating layer other than the organic insulating layer may not be disposed between the organic insulating layer and the pixel defining layer.

In an embodiment, the light emitting element may further include a cathode electrode disposed on the anode electrode and that receives a second power voltage, and the first power voltage has a higher voltage level than the second power voltage.

In an embodiment, the third gate layer may further include a first initialization voltage line that receives a first initialization voltage, a second initialization voltage line that receives a second initialization voltage, a first reference voltage line that receives a reference voltage, a gate line that receives a gate signal, and a bias voltage line that receives a bias voltage.

In an embodiment, each of the first power voltage line, the gate line, the first and second initialization voltage lines, the first reference voltage line, and the bias voltage line may extend in a first direction.

In an embodiment, the data conductive layer may include a second power voltage line that receives the first power voltage, a second reference voltage line that receives the reference voltage, and a data line that receives a data voltage. The second power voltage line may be connected to the first power voltage line and the second reference voltage line may be connected to the first reference voltage line.

In an embodiment, each of the second power voltage line, the second reference voltage line, and the data line may extend in a second direction intersecting the first direction.

In an embodiment, the active layer may include a first active pattern layer and a second active pattern layer spaced apart from each other. The first gate electrode may partially overlap the first active pattern layer, and the first gate electrode and a part of the first active pattern layer may form a first transistor.

In an embodiment, the first gate layer may further include a second gate electrode spaced apart from the first gate electrode and partially overlapping the second active pattern layer. The second gate electrode and a part of the second active pattern layer may form a second transistor.

In an embodiment, the third gate layer may further include a gate line spaced apart from the first power voltage line and that receives a gate signal. The gate line may be connected to the second gate electrode through a contact hole.

In an embodiment, the date conductive layer may include a data line that receives a data voltage. The data line may be connected to the second active pattern layer.

In an embodiment, the substrate may include a glass substrate.

In an embodiment, the third gate layer may include a low-resistance metal.

In an embodiment, the third gate layer may have a multi-layer structure including a titanium (Ti) layer, an aluminum (Al) layer, and a titanium (Ti) layer stacked with each other.

A display device according to embodiments may include a first transistor including a part of a first active pattern layer disposed on a substrate and a first gate electrode disposed on the first active pattern layer and partially overlapping the first active pattern layer, and that generates a driving current, a first capacitor including the first gate electrode, and a capacitor electrode disposed on the first gate electrode and overlapping the first gate electrode, a second capacitor including the capacitor electrode and a part of a first power voltage line disposed on the capacitor electrode, that receives a first power voltage, and overlapping the capacitor electrode, a data conductive layer disposed on the first power voltage line and including an anode connection pattern layer, an inorganic insulating layer disposed between the capacitor electrode and the data conductive layer, and covering the capacitor electrode, and a light emitting element disposed on the data conductive layer and including an anode electrode connected to the anode connection pattern layer and a cathode electrode that receives a second power voltage different from the first power voltage.

In an embodiment, the inorganic insulating layer may directly contact the first power voltage line.

In an embodiment, the display device may further include an organic insulating layer disposed between the data conductive layer and the anode electrode and a pixel defining layer disposed on the organic insulating layer and covering an edge portion of the anode electrode. Any organic insulating layer other than the organic insulating layer may not be disposed between the organic insulating layer and the pixel defining layer.

In an embodiment, the display device may further include a first initialization voltage line that receives a first initialization voltage, a second initialization voltage line that receives a second initialization voltage, a first reference voltage line that receives a reference voltage, a gate line that receives a gate signal, and a bias voltage line that receives a bias voltage. The first power voltage line, the gate line, the first and second initialization voltage lines, the first reference voltage line, and the bias voltage line may be formed as a same layer.

In an embodiment, each of the first power voltage line, the gate line, the first and second initialization voltage lines, the first reference voltage line, and the bias voltage line may extend in a first direction.

In an embodiment, the data conductive layer may include a second power voltage line that receives the first power voltage, a second reference voltage line that receives the reference voltage. and a data line that receives a data voltage. The second power voltage line may be connected to the first power voltage line, and the second reference voltage line may be connected to the first reference voltage line.

In an embodiment, each of the second power voltage line, the second reference voltage line, and the data line may extend in a second direction intersecting the first direction.

In an embodiment, the display device may further include a second transistor including a part of a second active pattern layer and a second gate electrode partially overlapping the second active pattern layer. The second active pattern layer and the first active pattern layer may be formed as a same layer, and the second gate electrode and the first gate electrode may be formed as a same layer.

In an embodiment, the display device may further include a gate line that receives a gate signal. The gate line and the first power voltage line may be formed as a same layer. The gate line may be connected to the second gate electrode through a contact hole.

In an embodiment, the date conductive layer may include a data line that receives a data voltage. The data line may be connected to the second active pattern layer.

A display device according to an embodiment may include an active layer, a first gate layer including a first gate electrode disposed on the active layer, a second gate layer disposed on the first gate layer and including a capacitor electrode, a third gate layer disposed on the second gate layer and including a first power voltage line, and a data conductive layer disposed on the third gate layer. The capacitor electrode may form a first capacitor together with the first gate electrode, and a part of the first power voltage line may form a second capacitor together with the capacitor electrode. The third gate layer may include a low-resistance metal. For example, an additional data conductive layer may not be disposed between a data conductive layer and a pixel electrode, and only one organic insulating layer may be disposed between the data conductive layer and a pixel defining layer. Accordingly, the display device may be implemented as a high-resolution rigid display device.

### BRIEF DESCRIPTION OF THE DRAWINGS

Illustrative, non-limiting embodiments will be more clearly understood from the following detailed description in conjunction with the accompanying drawings.

FIG. 1 is a schematic plan view illustrating a display device according to an embodiment.

FIG. 2 is a schematic diagram of an equivalent circuit of an example of a pixel included in a display panel of FIG. 1.

FIG. 3 is a schematic cross-sectional view schematically illustrating the display device of FIG. 1.

FIGS. 4, 5, 6, 7, 8, 9, 10, 11, and 12 are schematic layout views for explaining adjacent first and second pixel circuits of the display device according to an embodiment.

FIG. 13 is a schematic cross-sectional view taken along line I-I′ of FIG. 12.

FIG. 14 is a schematic cross-sectional view taken along line II-II′ of FIG. 12.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, a display device according to embodiments will be explained in detail with reference to the accompanying drawings. The same reference numerals are used for the same components in the drawings, and redundant descriptions of the same components will be omitted.

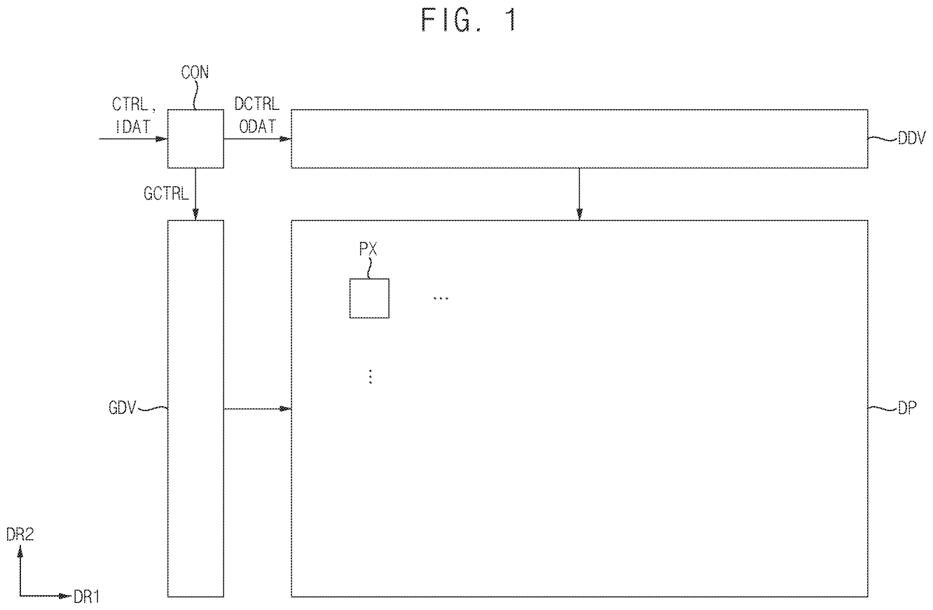

FIG. 1 is a schematic plan view illustrating a display device DD according to an embodiment.

Referring to FIG. 1, a display device DD according to an embodiment may include a display panel DP, a data driver DDV, a gate driver GDV, and a timing controller CON.

The display device DD may display an image through the display panel DP. For example, the display panel DP may include pixels PX, each of which includes a transistor and a light emitting element electrically connected to the transistor. The light emitting element may emit light by receiving a signal from the transistor. For example, the display device DD may display an image by the pixels PX which emits light.

A pixel PX may display a selected basic color. For example, the pixel (or single pixel) PX may be the minimum unit capable of displaying a color independent of other pixels PX. For example, the pixel PX may display any one color among red, green, and blue.

The pixels PX may be arranged in a matrix form along a first direction DR1 and a second direction DR2 intersecting the first direction DR1. For example, the first direction DR1 and the second direction DR2 may be perpendicular.

The timing controller CON may generate a gate control signal GCTRL, a data control signal DCTRL, and an output image data ODAT based on a control signal CTRL and an input image data IDAT provided from the outside. For example, the control signal CTRL may include a vertical synchronization signal, a horizontal synchronization signal, an input data enable signal, a master clock signal, and the like. For example, the input image data IDAT may be a RGB data including red image data, green image data, and blue image data. In another example, the input image data IDAT may include magenta image data, cyan image data, and yellow image data.

The gate driver GDV may generate gate signals based on a gate control signal GCTRL provided from the timing controller CON. For example, the gate control signal GCTRL may include a vertical start signal, a clock signal, and the like. For example, the gate driver GDV may be manufactured as a separate panel and connected to the display panel DP. The gate driver GDV may be electrically connected to the display panel DP and may sequentially output the gate signals. Each of the pixels PX may receive data voltages from the data driver DDV according to the control of each of the gate signals.

The data driver DDV may generate the data voltages based on a data control signal DCTRL and the output image data ODAT provided from the timing controller CON. For example, the data control signal DCTRL may include an output data enable signal, a horizontal start signal, a load signal, and the like. For example, the data driver DDV may be manufactured as a separate panel and electrically connected to the display panel DP. Each of the pixels PX may transmit a signal for luminance corresponding to each of the data voltages to the light emitting element.

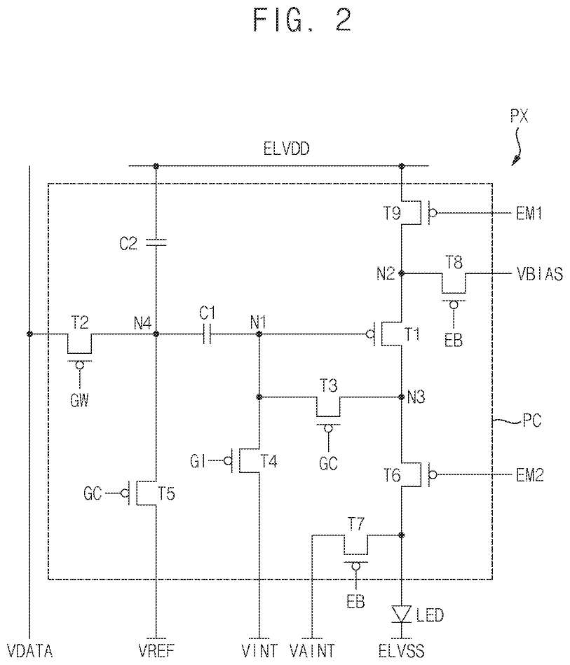

FIG. 2 is a schematic diagram of an equivalent circuit of an example of a pixel included in a display panel of FIG. 1.

Referring to FIG. 2, each pixel PX may include a pixel circuit PC and a light emitting element LED electrically connected to the pixel circuit PC. The pixel circuit PC may generate a driving current, and the light emitting element LED may generate light based on the driving current. For example, the pixel circuit PC may include first, second, third, fourth, fifth, sixth, seventh, eighth, and ninth transistors T1, T2, T3, T4, T5, T6, T7, T8, and T9, a first capacitor C1, and a second capacitor C2.

The first transistor T1 may include a first electrode, a second electrode, and a gate electrode. The gate electrode of the first transistor T1 may be connected to a first node N1. The first electrode of the first transistor T1 may be connected to a second node N2. The second electrode of the first transistor T1 may be connected to a third node N3. The first transistor T1 may be referred to as a driving transistor.

The first transistor T1 may generate the driving current based on the difference between a data voltage VDATA and a first power voltage ELVDD. The first transistor T1 may provide the driving current to the light emitting element LED.

The second transistor T2 may include a first electrode, a second electrode, and a gate electrode. A first gate signal GW may be applied to the gate electrode of the second transistor T2. The data voltage VDATA may be applied to the first electrode of the second transistor T2. The second electrode of the second transistor T2 may be connected to a fourth node N4. The second transistor T2 may provide the data voltage VDATA to the fourth node N4 in response to the first gate signal GW. The first gate signal GW may be referred to as a data write signal.

The third transistor T3 may include a first electrode, a second electrode, and a gate electrode. A second gate signal GC may be applied to the gate electrode of the third transistor T3. The first electrode of the third transistor T3 may be connected to the first node N1. The second electrode of the third transistor T3 may be connected to the third node N3. The third transistor T3 may compensate for a threshold voltage of the first transistor T1 by diode-connecting the first transistor T1 in response to the second gate signal GC. The second gate signal GC may be referred to as a compensation gate signal.

As shown in FIG. 2, the third transistor T3 may have a single transistor structure. In an embodiment, the third transistor T3 may have a dual transistor structure in which two transistors are connected in series. However, embodiments are not limited thereto.

The fourth transistor T4 may include a first electrode, a second electrode, and a gate electrode. A third gate signal GI may be applied to the gate electrode of the fourth transistor T4. A first initialization voltage VINT may be applied to the first electrode of the fourth transistor T4. The second electrode of the fourth transistor T4 may be connected to the first node N1. The fourth transistor T4 may provide the first initialization voltage VINT to the gate electrode of the first transistor T1 in response to the third gate signal GI. The third gate signal GI may be referred to as a data initialization gate signal.

As shown in FIG. 2, the fourth transistor T4 may have a single transistor structure. In an embodiment, the fourth transistor T4 may have a dual transistor structure in which two transistors are connected in series. However, embodiments are not limited thereto.

The fifth transistor T5 may include a first electrode, a second electrode, and a gate electrode. A second gate signal GC may be applied to the gate electrode of the fifth transistor T5. A reference voltage VREF may be applied to the first electrode of the fifth transistor T5. The second electrode of the fifth transistor T5 may be connected to the fourth node N4.

The sixth transistor T6 may include a first electrode, a second electrode, and a gate electrode. A second light emitting control signal EM2 may be applied to the gate electrode of the sixth transistor T6. The first electrode of the sixth transistor T6 may be connected to the third node N3. The second electrode of the sixth transistor T6 may be connected to the anode electrode of the light emitting element LED. The sixth transistor T6 may provide the driving current generated by the first transistor T1 to the light emitting element LED in response to the second light emitting control signal EM2.

The seventh transistor T7 may include a first electrode, a second electrode, and a gate electrode. A fourth gate signal EB may be applied to the gate electrode of the seventh transistor T7. A second initialization voltage VAINT may be applied to the first electrode of the seventh transistor T7. The second electrode of the seventh transistor T7 may be connected to the anode electrode of the light emitting element LED. The seventh transistor T7 may provide a second initialization voltage VAINT to an anode electrode of the light emitting element LED in response to the fourth gate signal EB. The fourth gate signal EB may be referred to as an initialization gate signal.

The eighth transistor T8 may include a first electrode, a second electrode, and a gate electrode. The fourth gate signal EB may be applied to the gate electrode of the eighth transistor T8. A bias voltage VBIAS may be applied to the first electrode of the eighth transistor T8. The second electrode of the eighth transistor T8 may be connected to the second node N2. The eighth transistor T8 may provide a bias voltage VBIAS to the second node N2 in response to the fourth gate signal EB.

The ninth transistor T9 may include a first electrode, a second electrode, and a gate electrode. A first light emitting control signal EM1 may be applied to the gate electrode of the ninth transistor T9. The first power voltage ELVDD may be applied to the first electrode of the ninth transistor T9. The second electrode of the ninth transistor T9 may be connected to the second node N2. The ninth transistor T9 may provide the first power voltage ELVDD to the first transistor T1 in response to the first light emitting control signal EM1.

The first capacitor C1 may include a first electrode and a second electrode. The first electrode of the first capacitor C1 may be connected to the first node N1. The second electrode of the first capacitor C1 may be connected to the fourth node N4. In an embodiment, the first capacitor C1 may be a storage capacitor. The first capacitor C1 may function to receive the data voltage VDATA output from the second transistor T2 and maintain the data voltage VDATA at the voltage of the gate electrode of the first transistor T1.

The second capacitor C2 may include a first electrode and a second electrode. The first electrode of the second capacitor C2 may be connected to the fourth node N4. The first power voltage ELVDD may be applied to the second electrode of the second capacitor C2. In an embodiment, the second capacitor C2 may be a hold capacitor. The second capacitor C2 may maintain a constant voltage by holding the voltage of the first electrode of the first capacitor C1 without changing in case that the surrounding signal changes.

The light emitting element LED may include the anode electrode and the cathode electrode. The anode electrode of the light emitting element LED may be connected to the second electrode of the seventh transistor T7. A second power voltage ELVSS may be applied to the cathode electrode of the light emitting element LED. The voltage level of the second power voltage ELVSS may be lower than the voltage level of the first power voltage ELVDD.

In an embodiment, each of the first, second, third, fourth, fifth, sixth, seventh, eighth, and ninth transistors T1, T2, T3, T4, T5, T6, T7, T8, and T9 may be a PMOS transistor. However, embodiments are not limited thereto, and at least one of the first, second, third, fourth, fifth, sixth, seventh, eighth, and ninth transistors T1, T2, T3, T4, T5, T6, T7, T8, and T9 may be an NMOS transistor.

However, although the pixel circuit PC has been described as including nine transistors and two capacitors, embodiments are not limited thereto.

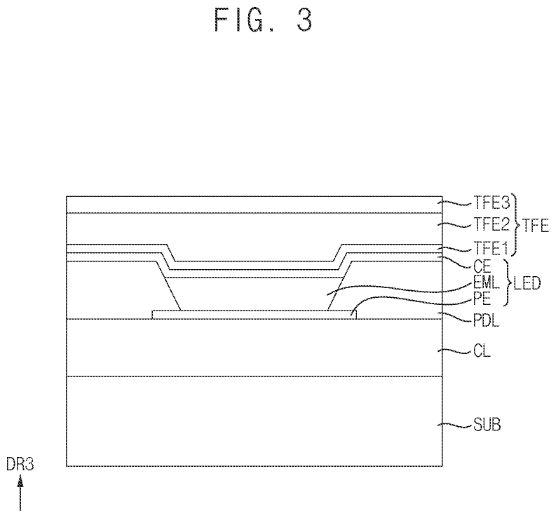

FIG. 3 is a schematic cross-sectional view schematically illustrating the display device DD of FIG. 1. For example, FIG. 3 is a schematic cross-sectional view schematically illustrating an example of a cross-section of the display panel DP of FIG. 1.

Referring to FIG. 3, the display device DD according to an embodiment may include a substrate SUB, a circuit layer CL, the light emitting element LED, a pixel defining layer PDL, and an encapsulation layer TFE.

The substrate SUB may include a transparent material or an opaque material. In an embodiment, the substrate SUB may include a rigid glass substrate. For example, the substrate SUB may include a quartz substrate, a synthetic quartz substrate, a calcium fluoride substrate, a fluorine-doped quartz substrate, a soda-lime substrate, a non-alkali glass substrate, and the like. These may be used alone or in combination with each other.

The circuit layer CL may be disposed on the substrate SUB in a third direction DR3. The circuit layer CL may provide signals and voltages for the light emitting element LED to emit light to the light emitting element LED. For example, the circuit layer CL may include a transistor, a capacitor, an insulating layer, and the like. The third direction DR3 may be perpendicular to a plane defined by the first direction DR1 and the second direction DR2 of FIG. 1.

A pixel electrode PE may be disposed on the circuit layer CL in the third direction DR3. The pixel electrode PE may receive the signals and voltages from the circuit layer CL. For example, the pixel electrode PE may include metal, alloy, metal nitride, conductive metal oxide, transparent conductive material, and the like. These may be used alone or in combination with each other. For example, the pixel electrode PE may be an anode electrode.

The pixel defining layer PDL may be disposed on the circuit layer CL and the pixel electrode PE. The pixel defining layer PDL may cover an edge portion of the pixel electrode PE. For example, an opening that exposes at least a part of an upper surface of the pixel electrode PE may be defined in the pixel defining layer PDL. By defining the opening in the pixel defining layer PDL, the pixel defining layer PDL may define the pixel PX which emits light. The pixel defining layer PDL may include organic materials and/or inorganic materials. For example, the pixel defining layer PDL may include organic materials such as photoresist, polyacrylic resin, polyimide resin, polyamide resin, siloxane resin, acrylic resin, epoxy resin, and the like. These may be used alone or in combination with each other.

A light emitting layer EML may be disposed on the pixel electrode PE. For example, the light emitting layer EML may be disposed in the opening of the pixel defining layer PDL. The light emitting layer EML may include materials for emitting light. For example, the light emitting layer EML may include an organic light emitting material and/or an inorganic light emitting material.

A common electrode CE may be disposed on the pixel defining layer PDL and the light emitting layer EML. For example, the common electrode CE may include metal, alloy, metal nitride, conductive metal oxide, transparent conductive material, and the like. These may be used alone or in combination with each other. For example, the common electrode CE may be a cathode electrode.

Accordingly, the light emitting element LED including the pixel electrode PE, the light emitting layer EML, and the common electrode CE may be disposed on the substrate SUB.

The encapsulation layer TFE may be disposed on the common electrode CE. The encapsulation layer TFE may protect the light emitting element LED from external oxygen and moisture. The encapsulation layer TFE may include at least one inorganic layer and at least one organic layer. For example, the encapsulation layer TFE may include a first inorganic layer TFE1, an organic layer TFE2 disposed on the first inorganic layer TFE1, and a second inorganic layer TFE3.

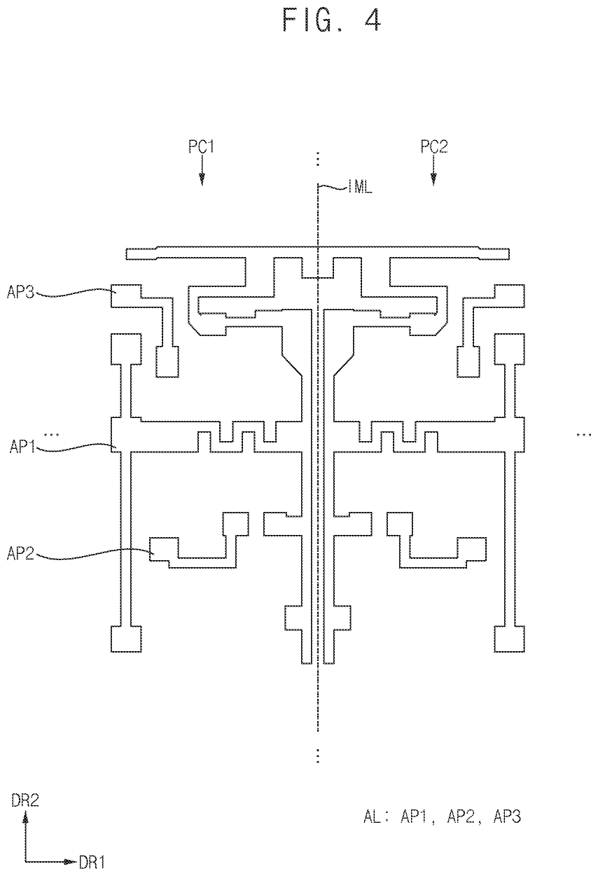

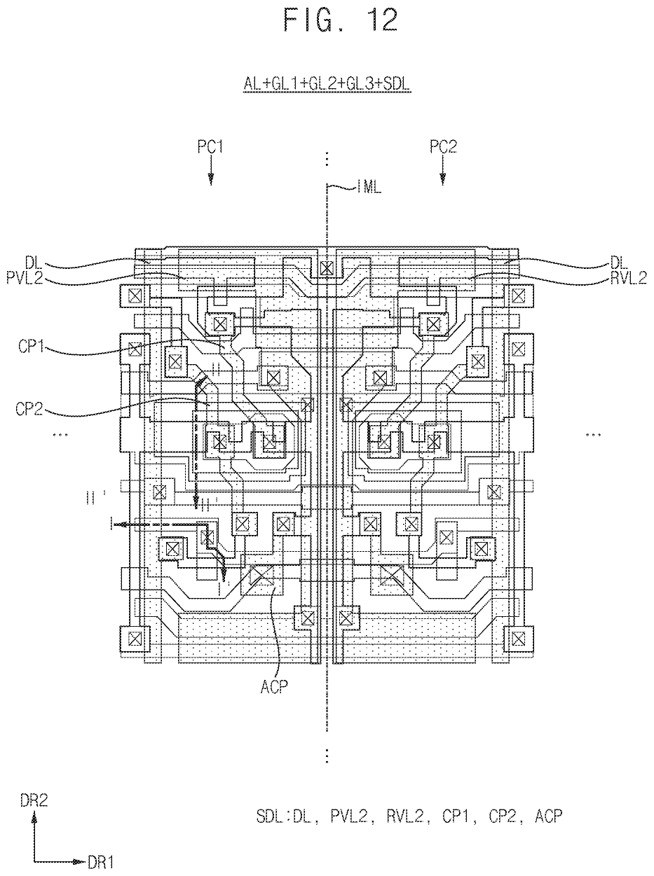

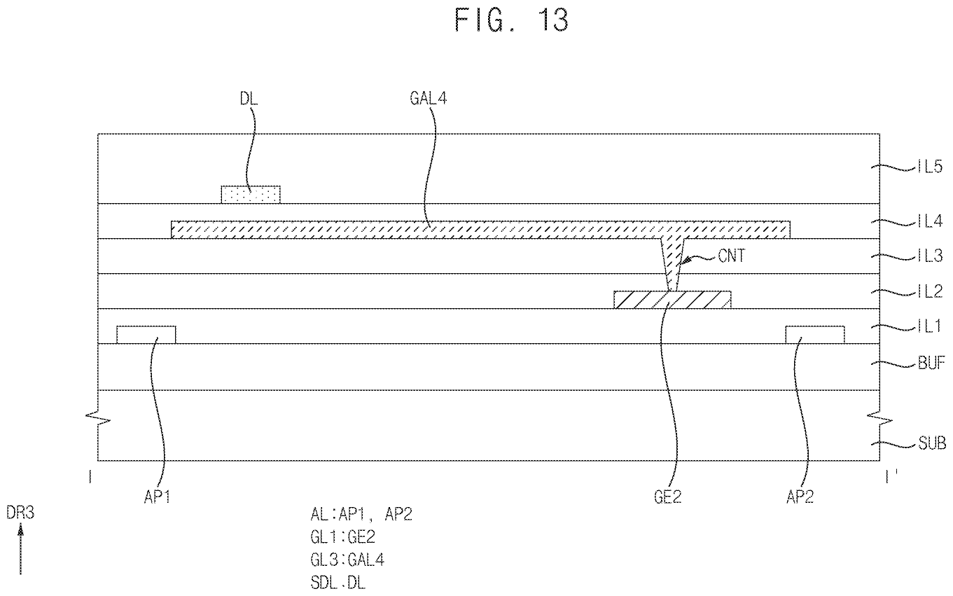

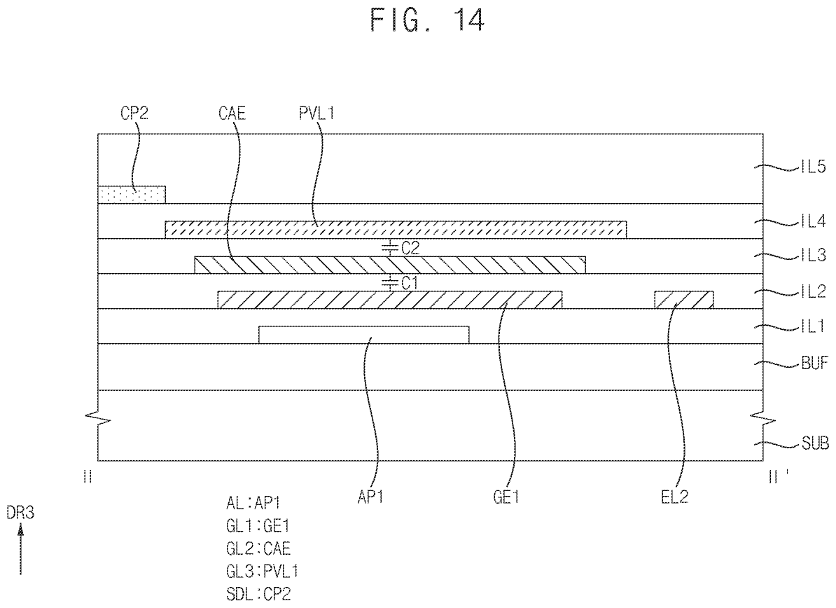

FIGS. 4, 5, 6, 7, 8, 9, 10, 11, and 12 are schematic layout views for explaining adjacent first and second pixel circuits PC1 and PC2 of the display device DD according to an embodiment. FIG. 13 is a schematic cross-sectional view taken along line I-I′ of FIG. 12. FIG. 14 is a schematic cross-sectional view taken along line II-II′ of FIG. 12. For example, FIGS. 4, 5, 6, 7, 8, 9, 10, 11, and 12 are schematic layout views illustrating components of the display panel DP of FIG. 1. FIGS. 4, 5, 6, 7, 8, 9, 10, 11, and 12 are schematic layout views illustrating components of the circuit layer CL of FIG. 3.

Referring to FIG. 4, the display panel DP may include a first pixel circuit PC1 and a second pixel circuit PC2 adjacent to each other. In an embodiment, the second pixel circuit PC2 may have a structure in which the structure of the first pixel circuit PC1 is symmetrical based on an imaginary symmetry line IML extending in the second direction DR2. Each of the first pixel circuit PC1 and the second pixel circuit PC2 may correspond to the pixel circuit PC of FIG. 2.

The display panel DP may include an active layer AL disposed on a substrate (e.g., the substrate SUB of FIG. 3). For example, a buffer layer BUF may be disposed on the substrate, and the active layer AL may be disposed on the buffer layer BUF. For example, the buffer layer BUF may include a silicon compound such as silicon oxide, silicon nitride, and the like. These may be used alone or in combination with each other (see FIGS. 12 and 13).

The active layer AL may include a first active pattern layer AP1, a second active pattern layer AP2, and a third active pattern layer AP3. The first active pattern layer AP1, the second active pattern layer AP2, and the third active pattern layer AP3 may be spaced apart from each other.

The first active pattern layer AP1, the second active pattern layer AP2, and the third active pattern layer AP3 may be formed as the same layer or disposed in the same layer. For example, the first active pattern layer AP1, the second active pattern layer AP2, and the third active pattern layer AP3 may include the same material and be formed by the same process.

The first active pattern layer AP1 may be shared by a first area where the first pixel circuit PC1 is disposed and a second area where the second pixel circuit PC2 is disposed. For example, the first active pattern layer AP1 may include a first part disposed in the first area and a second part disposed in the second area. For example, the first part of the first active pattern layer AP1 may be symmetrical with the second part based on the imaginary symmetry line IML.

The second active pattern layer AP2 may be disposed in each of the first pixel circuit PC1 and the second pixel circuit PC2. The second active pattern layer AP2 disposed in the first pixel circuit PC1 and the second active pattern layer AP2 disposed in the second pixel circuit PC2 may be symmetrical to each other based on the imaginary symmetry line IML.

The third active pattern layer AP3 may be disposed in each of the first pixel circuit PC1 and the second pixel circuit PC2. The third active pattern layer AP3 disposed in the first pixel circuit PC1 and the third active pattern layer AP3 disposed in the second pixel circuit PC2 may be symmetrical to each other based on the imaginary symmetry line IML.

In an embodiment, the active layer AL may include a silicon semiconductor such as amorphous silicon or polycrystalline silicon. However, embodiments are not limited thereto, and the active layer AL may include a metal oxide semiconductor.

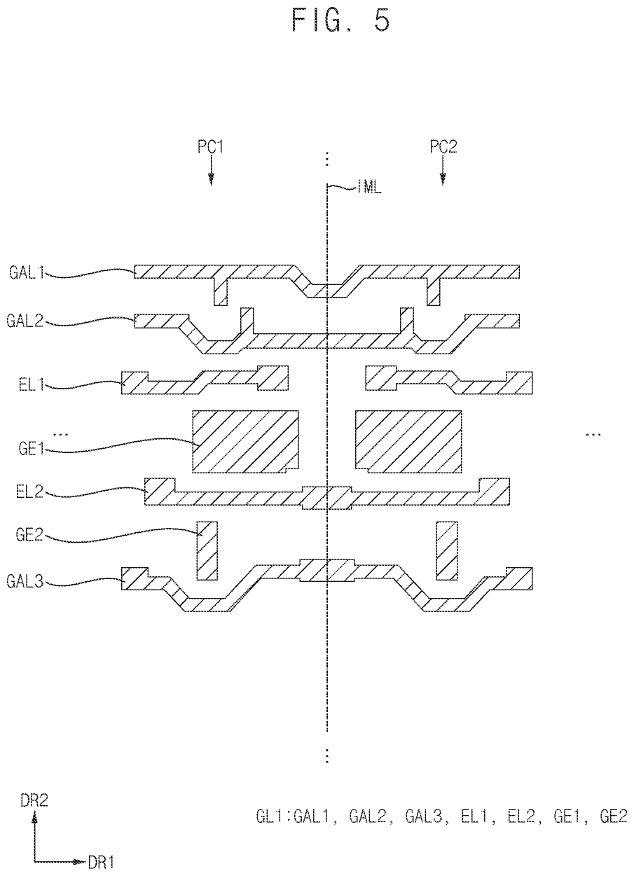

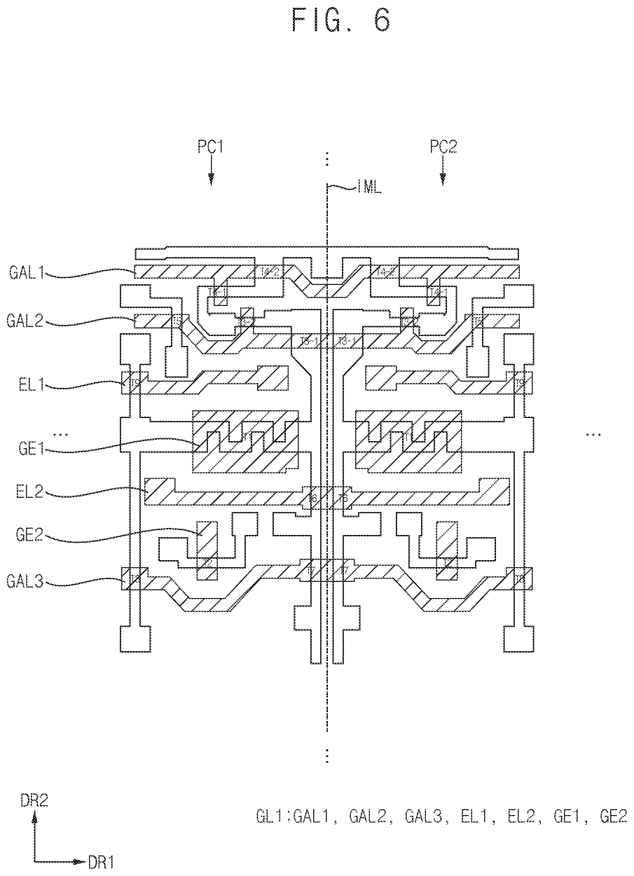

Referring further to FIGS. 5 and 6, the display panel DP may further include a first gate layer GL1 disposed on the active layer AL. For example, the first insulating layer IL1 may be disposed on the active layer, and the first gate layer GL1 may be disposed on the first insulating layer IL1. For example, the first insulating layer IL1 may include a silicon compound such as silicon oxide, silicon nitride, and the like. These may be used alone or in combination with each other (see FIGS. 13 and 14). The first insulating layer IL1 may be referred to as an inorganic insulating layer.

The first gate layer GL1 may include a first gate line GAL1, a second gate line GAL2, a third gate line GAL3, a first light emitting control line EL1, a second light emitting control line EL2, a first gate electrode GE1, and a second gate electrode GE2. The first gate line GAL1, the second gate line GAL2, the third gate line GAL3, the first light emitting control line EL1, the second light emitting control line EL2, the first gate electrode GE1, and the second gate electrode GE2 may be spaced apart from each other.

The first gate line GAL1, the second gate line GAL2, the third gate line GAL3, the first light emitting control line EL1, the second light emitting control line EL2, the first gate electrode GE1, and the second gate electrode GE2 may be formed as the same layer or disposed in the same layer. For example, the first gate line GAL1, the second gate line GAL2, the third gate line GAL3, the first light emitting control line EL1, the second light emitting control line EL2, the first gate electrode GE1, and the second gate electrode GE2 may include the same material and may be formed by the same process.

The first gate electrode GE1 may partially overlap the first active pattern layer AP1 in the plan view. The first gate electrode GE1 may be disposed in each of the first pixel circuit PC1 and the second pixel circuit PC2. The first gate electrode GE1 disposed in the first pixel circuit PC1 and the first gate electrode GE1 disposed in the second pixel circuit PC2 may be symmetrical to each other based on the imaginary symmetry line IML.

In an embodiment, the first gate electrode GE1 may form the first transistor T1 together with a part of the first active pattern layer AP1. The first transistor T1 of FIG. 6 may correspond to the first transistor T1 of FIG. 2.

The second gate electrode GE2 may partially overlap the second active pattern layer AP2 in the plan view. The second gate electrode GE2 may be disposed in each of the first pixel circuit PC1 and the second pixel circuit PC2. The second gate electrode GE2 disposed in the first pixel circuit PC1 and the second gate electrode GE2 disposed in the second pixel circuit PC2 may be symmetrical to each other based on the imaginary symmetry line IML.

In an embodiment, the second gate electrode GE2 may form the second transistor T2 together with a part of the second active pattern layer AP2. The second transistor T2 of FIG. 6 may correspond to the second transistor T2 of FIG. 2.

The first gate line GAL1 may extend in the first direction DR1. The first gate line GAL1 may partially overlap the first active pattern layer AP1 in the plan view. For example, a third gate signal (e.g., the third gate signal GI of FIG. 2) may be applied to the first gate line GAL1.

In an embodiment, a part of the first active pattern layer AP1 and a part of the first gate line GAL1 (e.g., gate electrode) overlapping the part of the first active pattern layer AP1 may form a fourth-first transistor T4-1, and another part of the first active pattern layer AP1 and a part of the first gate line GAL1 (e.g., gate electrode) overlapping another part of the first active pattern layer AP1 may form a fourth-second transistor T4-2.

The fourth-first transistor T4-1 and the fourth-second transistor T4-2 may be connected to each other in series. Accordingly, the fourth-first transistor T4-1 and the fourth-second transistor T4-2 may define a fourth transistor, and the fourth transistor may correspond to the fourth transistor T4 of FIG. 2.

The second gate line GAL2 may extend in the first direction DR1. The second gate line GAL2 may partially overlap each of the first active pattern layer AP1 and the third active pattern layer AP3 in the plan view. For example, a second gate signal (e.g., the second gate signal GC of FIG. 2) may be applied to the second gate line GAL2.

In an embodiment, a part of the first active pattern layer AP1 and a part of the second gate line GAL2 (e.g., gate electrode) overlapping the part of the first active pattern layer AP1 may form a third-first transistor T3-1, and another part of the first active pattern layer AP1 and a part of the second gate line GAL2 (e.g., gate electrode) overlapping another part of the first active pattern layer AP1 may form a third-second transistor T3-2.

The third-first transistor T3-1 and the third-second transistor T3-2 may be connected to each other in series. Accordingly, the 3 third-first transistor T3-1 and the third-second transistor T3-2 may define a third transistor, and the third transistor may correspond to the third transistor T3 of FIG. 2.

In an embodiment, a part of the third active pattern layer AP3 and a part of the second gate line GAL2 (e.g., gate electrode) overlapping the part of the third active pattern layer AP3 may form the fifth transistor T5. The fifth transistor T5 of FIG. 6 may correspond to the fifth transistor T5 of FIG. 2.

The third gate line GAL3 may extend in the first direction DR1. The third gate line GAL3 may partially overlap the first active pattern layer AP1 in the plan view. For example, a fourth gate signal (e.g., the fourth gate signal EB of FIG. 2) may be applied to the third gate line GAL3.

In an embodiment, a part of the first active pattern layer AP1 and a part of the third gate line GAL3 (e.g., gate electrode) overlapping the part of the first active pattern layer AP1 may form the seventh transistor T7. The seventh transistor T7 of FIG. 6 may correspond to the seventh transistor T7 of FIG. 2.

In an embodiment, another part of the first active pattern layer AP1 and a part of the third gate line GAL3 (e.g., gate electrode) overlapping another part of the first active pattern layer AP1 may form the eighth transistor T8. The eighth transistor T8 of FIG. 6 may correspond to the eighth transistor T8 of FIG. 2.

The first light emitting control line EL1 may extend in the first direction DR1. The first light emitting control line EL1 may partially overlap the first active pattern layer AP1 in the plan view. For example, a first light emitting control signal (e.g., the first light emitting control signal EM1 of FIG. 2) may be applied to the first light emitting control line EL1.

The first light emitting control line EL1 may be disposed in each of the first pixel circuit PC1 and the second pixel circuit PC2.

The first light emitting control line EL1 disposed in the first pixel circuit PC1 and the first light emitting control line EL1 disposed in the second pixel circuit PC2 may be symmetrical to each other based on the imaginary symmetry line IML.

In an embodiment, a part of the first active pattern layer AP1 and a part of the first light emitting control line EL1 (e.g., gate electrode) overlapping the part of the first active pattern layer AP1 may form the ninth transistor T9. The ninth transistor T9 of FIG. 6 may correspond to the ninth transistor T9 of FIG. 2.

The second light emitting control line EL2 may extend in the first direction DR1. The second light emitting control line EL2 may be shared by a first area where the first pixel circuit PC1 is disposed and a second area where the second pixel circuit PC2 is disposed. For example, the second light emitting control line EL2 may include a first part disposed in the first area and a second part disposed in the second area. For example, the first part of the second light emitting control line EL2 may be symmetrical with the second part based on the imaginary symmetry line IML.

The second light emitting control line EL2 may partially overlap the first active pattern layer AP1 in the plan view. For example, a second light emitting control signal (e.g., the second light emitting control signal EM2 of FIG. 2) may be applied to the second light emitting control line EL2.

In an embodiment, a part of the first active pattern layer AP1 and a part of the second light emitting control line EL2 (e.g., gate electrode) overlapping the part of the first active pattern layer AP1 may form the sixth transistor T6. The sixth transistor T6 of FIG. 6 may correspond to the sixth transistor T6 of FIG. 2.

Accordingly, the first pixel circuit PC1 may include the first, second, third, fourth, fifth, sixth, seventh, eighth, and ninth transistors T1, T2, T3, T4, T5, T6, T7, T8, and T9, and the second pixel circuit PC2 may also include the first, second, third, fourth, fifth, sixth, seventh, eighth, and ninth transistors T1, T2, T3, T4, T5, T6, T7, T8, and T9.

The first pixel circuit PC1 and a pixel circuit adjacent to the first pixel circuit PC1 in a direction opposite to the first direction DR1 may share the eighth and ninth transistors T8 and T9. For example, the second pixel circuit PC2 and a pixel circuit adjacent to the second pixel circuit PC2 in the first direction DR1 may share the eighth and ninth transistors T8 and T9.

For example, the first gate layer GL1 may include metal, alloy, metal nitride, conductive metal oxide, transparent conductive material, and the like. These may be used alone or in combination with each other. In an embodiment, the first gate layer GL1 may include molybdenum (Mo). However, embodiments are not limited thereto.

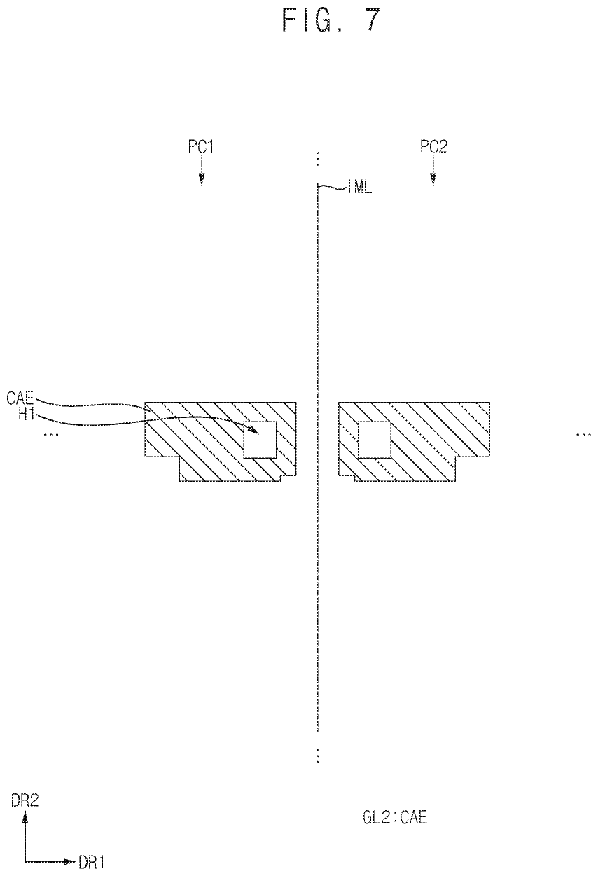

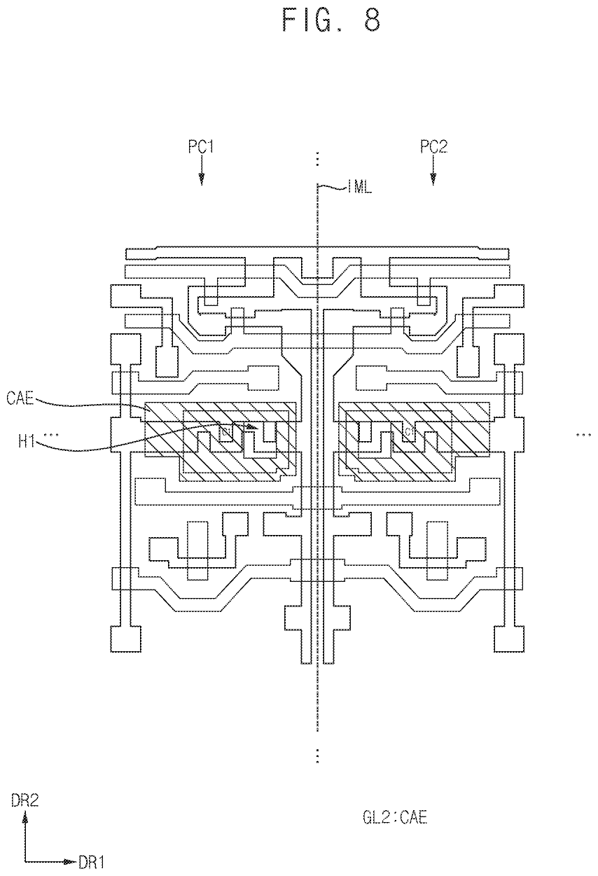

Referring further to FIGS. 7 and 8, the display panel DP may further include a second gate layer GL2 disposed on the first gate layer GL1. For example, a second insulating layer IL2 may cover the first gate layer GL1, and the second gate layer GL2 may be disposed on the second insulating layer IL2. For example, the second insulating layer IL2 may include a silicon compound such as silicon oxide, silicon nitride, and the like. These may be used alone or in combination with each other (see FIGS. 13 and 14). The second insulating layer IL2 may be referred to as an inorganic insulating layer.

The second gate layer GL2 may include a capacitor electrode CAE. A first hole H1 may be defined in the capacitor electrode CAE. The first hole H1 may expose at least a part of the first gate electrode GE1.

The capacitor electrode CAE may partially overlap the first gate electrode GE1 in the plan view. The capacitor electrode CAE may be disposed in each of the first pixel circuit PC1 and the second pixel circuit PC2. The capacitor electrode CAE disposed in the first pixel circuit PC1 and the capacitor electrode CAE disposed in the second pixel circuit PC2 may be symmetrical based on the imaginary symmetry line IML.

In an embodiment, the capacitor electrode CAE may form the first capacitor C1 together with the first gate electrode GE1. The first capacitor C1 of FIG. 8 may correspond to the first capacitor C1 of FIG. 2. The first gate electrode GE1 may correspond to the first electrode of the first capacitor C1, and the capacitor electrode CAE may correspond to the second electrode of the first capacitor C1.

Accordingly, the first pixel circuit PC1 may include the first capacitor C1, and the second pixel circuit PC2 may also include the first capacitor C1.

For example, the second gate layer GL2 may include metal, alloy, metal nitride, conductive metal oxide, transparent conductive material, and the like. These may be used alone or in combination with each other. In an embodiment, the first gate layer GL1 may include molybdenum (Mo). However, embodiments are not limited thereto.

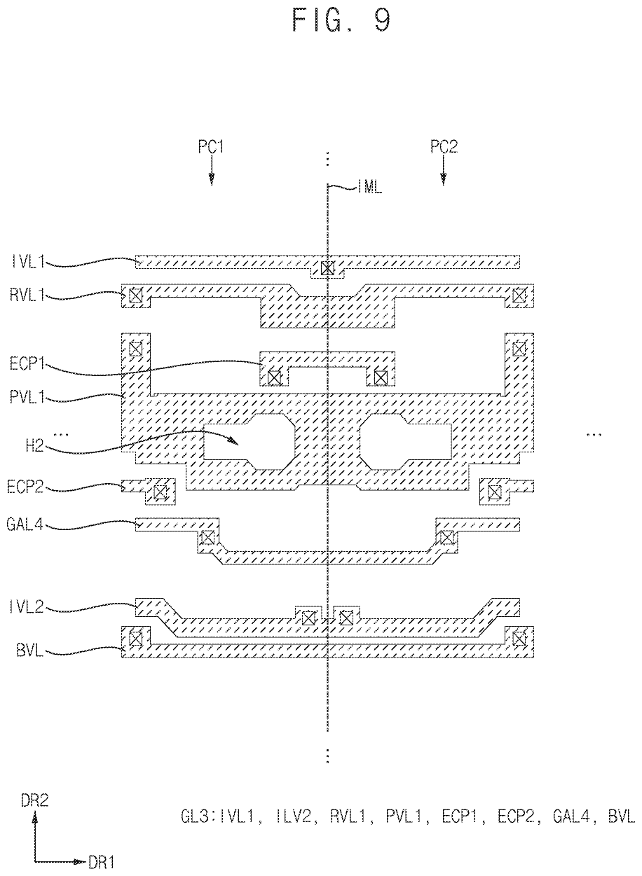

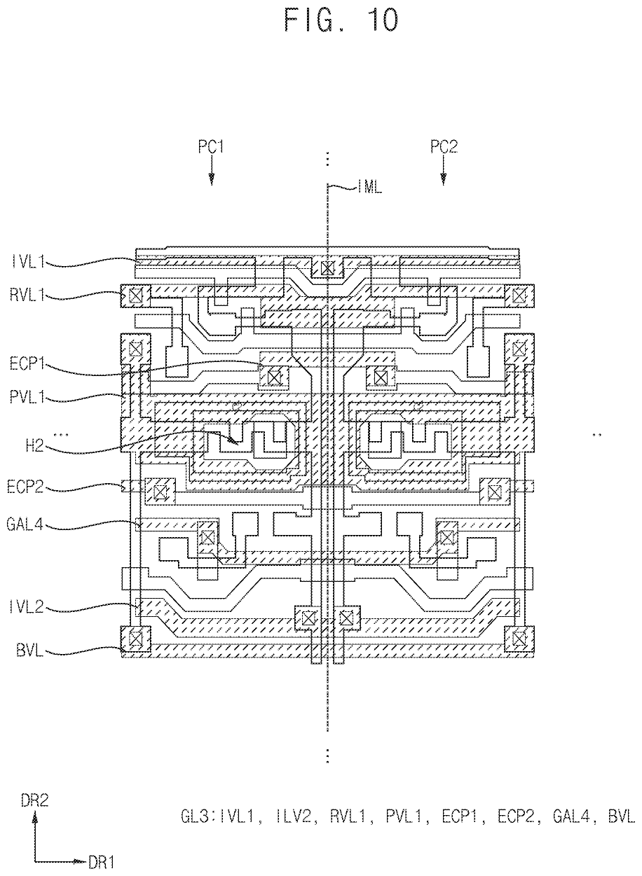

Referring further to FIGS. 9 and 10, the display panel DP may further include a third gate layer GL3 disposed on the second gate layer GL2. For example, a third insulating layer IL3 may be disposed covering the second gate layer GL2, and the third gate layer GL3 may be disposed on the third insulating layer IL3. For example, the third insulating layer IL3 may include a silicon compound such as silicon oxide, silicon nitride, and the like. These may be used alone or in combination with each other (see FIGS. 13 and 14). The third insulating layer IL3 may be referred to as an inorganic insulating layer.

The third gate layer GL3 may include a first initialization voltage line IVL1, a second initialization voltage line IVL2, a first reference voltage line RVL1, a first power voltage line PVL1, a first light emitting control connection pattern layer ECP1, a second light emitting control connection pattern layer ECP2, a fourth gate line GAL4, and a bias voltage line BVL. The first initialization voltage line IVL1, the second initialization voltage line IVL2, the first reference voltage line RVL1, the first power voltage line PVL1, the first light emitting control connection pattern layer ECP1, the second light emitting control connection pattern layer ECP2, the fourth gate line GAL4, and the bias voltage line BVL may be spaced apart from each other.

The first initialization voltage line IVL1, the second initialization voltage line IVL2, the first reference voltage line RVL1, the first power voltage line PVL1, the first light emitting control connection pattern layer ECP1, the second light emitting control connection pattern layer ECP2, the fourth gate line GAL4, and the bias voltage line BVL may be formed as the same layer or disposed in the same layer. For example, the first initialization voltage line IVL1, the second initialization voltage line IVL2, the first reference voltage line RVL1, the first power voltage line PVL1, the first light emitting control connection pattern layer ECP1, the second light emitting control connection pattern layer ECP2, the fourth gate line GAL4, and the bias voltage line BVL may include the same material and may be formed by the same process.

The first initialization voltage line IVL1 may extend in the first direction DR1. A first initialization voltage (e.g., the first initialization voltage VINT of FIG. 2) may be applied to the first initialization voltage line IVL1. For example, the first initialization voltage line IVL1 may be connected to the first active pattern layer AP1 through a contact hole. Accordingly, the first initialization voltage line IVL1 may transmit the first initialization voltage to the first active pattern layer AP1. For example, the fourth transistor T4 may receive the first initialization voltage.

The second initialization voltage line IVL2 may extend in the first direction DR1. A second initialization voltage (e.g., the second initialization voltage VAINT of FIG. 2) may be applied to the second initialization voltage line IVL2. For example, the second initialization voltage line IVL2 may be connected to the first active pattern layer AP1 through a contact hole. Accordingly, the second initialization voltage line IVL2 may transmit the second initialization voltage to the first active pattern layer AP1. For example, the seventh transistor T7 may receive the second initialization voltage.

The first reference voltage line RVL1 may extend in the first direction DR1. A reference voltage (e.g., reference voltage VREF of FIG. 2) may be applied to the first reference voltage line RVL1. For example, the first reference voltage line RVL1 may be connected to the third active pattern layer AP3 through a contact hole. Accordingly, the first reference voltage line RVL1 may transmit the reference voltage to the third active pattern layer AP3. For example, the fifth transistor T5 may receive the reference voltage.

The bias voltage line BVL may extend in the first direction DR1. A bias voltage (e.g., bias voltage VBIAS of FIG. 2) may be applied to the bias voltage line BVL. For example, the bias voltage line BVL may be connected to the first active pattern layer AP1 through a contact hole. Accordingly, the bias voltage line BVL may transmit the bias voltage to the first active pattern layer AP1. For example, the eighth transistor T8 may receive the bias voltage.

The first light emitting control connection pattern layer ECP1 may connect the first light emitting control line EL1 disposed in the first pixel circuit PC1 and the first light emitting control line EL1 disposed in the second pixel circuit PC2 through a contact hole.

The second light emitting control connection pattern layer ECP2 may be disposed in each of the first pixel circuit PC1 and the second pixel circuit PC2. For example, the second light emitting control connection pattern layer ECP2 disposed in the first pixel circuit PC1 and the second light emitting control connection pattern layer ECP2 disposed in the second pixel circuit PC2 may be symmetrical to each other. The second light emitting control connection pattern layer ECP2 may be connected to the second light emitting control line EL2 through a contact hole.

The first power voltage line PVL1 may extend in the first direction DR1. The first power voltage line PVL1 may partially overlap the capacitor electrode CAE in the plan view. For example, a second hole H2 may be defined in the first power voltage line PVL1. The second hole H2 may expose at least a part of the capacitor electrode CAE.

The first power voltage line PVL1 may be connected to the first active pattern layer AP1 through a contact hole. For example, a first power voltage (e.g., the first power voltage ELVDD of FIG. 2) may be applied to the first power voltage line PVL1. Accordingly, the first power voltage line PVL1 may transmit the first power voltage to the first active pattern layer AP1. For example, the ninth transistor T9 may receive the first power voltage.

In an embodiment, a part of the first power voltage line PVL1 may form the second capacitor C2 together with the capacitor electrode CAE. The second capacitor C2 of FIG. 10 may correspond to the second capacitor C2 of FIG. 2. The capacitor electrode CAE may correspond to the first electrode of the second capacitor C2, and the part of the first power voltage line PVL1 may correspond to the second electrode of the second capacitor C2.

Accordingly, the first pixel circuit PC1 may include the second capacitor C2, and the second pixel circuit PC2 may also include the second capacitor C2.

As a result, the second capacitor C2 may overlap the first capacitor C1 in a vertical direction (e.g., the third direction DR3 of FIG. 3).

The fourth gate line GAL4 may extend in the first direction DR1. A first gate signal (e.g., the first gate signal GW of FIG. 2) may be applied to the fourth gate line GAL4. For example, the fourth gate line GAL4 may be connected to the second gate electrode GE2 through a contact hole CNT (see FIG. 13). Accordingly, the fourth gate line GAL4 may transmit the first gate signal to the second gate electrode GE2.

For example, the third gate layer GL3 may include metal, alloy, metal nitride, conductive metal oxide, transparent conductive material, and the like. These may be used alone or in combination with each other. In an embodiment, the third gate layer GL3 may include a low-resistance metal. For example, the third gate layer GL3 may have a multi-layer structure including a titanium (Ti) layer, an aluminum (Al) layer, and a titanium (Ti) layer disposed sequentially. However, embodiments are not limited thereto.

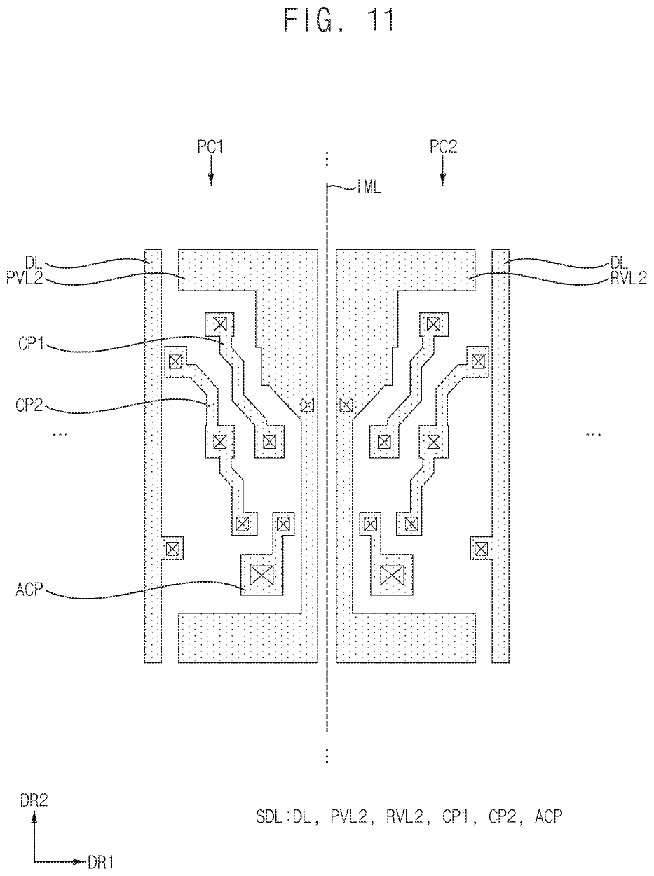

Referring further to FIGS. 11 and 12, the display panel DP may further include a data conductive layer SDL disposed on the third gate layer GL3. For example, a fourth insulating layer IL4 may cover the third gate layer GL3, and the data conductive layer SDL may be disposed on the fourth insulating layer IL4. For example, the fourth insulating layer IL4 may include a silicon compound such as silicon oxide, silicon nitride, and the like. These may be used alone or in combination with each other (see FIGS. 13 and 14). The fourth insulating layer IL4 may be referred to as an inorganic insulating layer.

In an embodiment, the fourth insulating layer IL4 may directly contact the third gate layer GL3. For example, the third gate layer GL3 may not directly contact an organic insulating layer.

The data conductive layer SDL may include a data line DL, a second power voltage line PVL2, a second reference voltage line RVL2, a first connection pattern layer CP1, a second connection pattern layer CP2, and an anode connection pattern layer ACP. The data line DL, the second power voltage line PVL2, the second reference voltage line RVL2, the first connection pattern layer CP1, the second connection pattern layer CP2, and the anode connection pattern layer ACP may be spaced apart from each other.

The data line DL, the second power voltage line PVL2, the second reference voltage line RVL2, the first connection pattern layer CP1, the second connection pattern layer CP2, and the anode connection pattern layer ACP may be formed as the same layer or disposed in the same layer. For example, the data line DL, the second power voltage line PVL2, the second reference voltage line RVL2, the first connection pattern layer CP1, the second connection pattern layer CP2, and the anode connection pattern layer ACP may include the same material and may be formed by the same process.

The data line DL may extend in the second direction DR2. A data voltage (e.g., the data voltage VDATA of FIG. 2) may be applied to the data line DL. For example, the data line DL may be connected to the second active pattern layer AP2 through a contact hole. Accordingly, the data line DL may transmit the data voltage to the second active pattern layer AP2. For example, the second transistor T2 may receive the data voltage. The data line DL may be disposed for each pixel circuit.

The second power voltage line PVL2 may extend in the second direction DR2. The second power voltage line PVL2 may be disposed in the first pixel circuit PC1. The first power voltage may be applied to the second power voltage line PVL2. For example, the second power voltage line PVL2 may be connected to the first power voltage line PVL1 through a contact hole. Accordingly, the second power voltage line PVL2 may form a mesh structure together with the first power voltage line PVL1.

The second reference voltage line RVL2 may extend in the second direction DR2. The second reference voltage line RVL2 may be disposed in the second pixel circuit PC2. The reference voltage may be applied to the second reference voltage line RVL2. For example, the second reference voltage line RVL2 may be connected to the first reference voltage line RVL1 through a contact hole. Accordingly, the second reference voltage line RVL2 may form a mesh structure together with the first reference voltage line RVL1.

The first connection pattern layer CP1 may connect the first active pattern layer AP1 and the first gate electrode GE1 through a contact hole. For example, the first connection pattern layer CP1 may be connected to the first gate electrode GE1 through a contact hole overlapping the first and second holes H1 and H2, and may be connected to the first active pattern layer AP1 through a contact hole. For example, the gate electrode of the first transistor T1 may be connected to a part of the first active pattern layer AP1 forming the third transistor through the first connection pattern layer CP1.

The first connection pattern layer CP1 may be disposed in each of the first pixel circuit PC1 and the second pixel circuit PC2. The first connection pattern layer CP1 disposed in the first pixel circuit PC1 and the first connection pattern layer CP1 disposed in the second pixel circuit PC2 may be symmetrical to each other based on the imaginary symmetry line IML.

The second connection pattern layer CP2 may connect the second active pattern layer AP2, the third active pattern layer AP3, and the capacitor electrode CAE through a contact hole. For example, the second connection pattern layer CP2 may be connected to the capacitor electrode CAE through a contact hole overlapping the second hole H2, and may be connected to the second active pattern layer AP2 and the third active pattern layer AP3 through the contact holes, respectively. For example, the second transistor T2, the fifth transistor T5, and the second capacitor C2 may be electrically connected through the second connection pattern layer CP2.

The second connection pattern layer CP2 may be disposed in each of the first pixel circuit PC1 and the second pixel circuit PC2. The second connection pattern layer CP2 disposed in the first pixel circuit PC1 and the second connection pattern layer CP2 disposed in the second pixel circuit PC2 may be symmetrical to each other based on the imaginary symmetry line IML.

The anode connection pattern layer ACP may be connected to the first active pattern layer AP1 through a contact hole. For example, the anode connection pattern layer ACP may be connected to a pixel electrode (e.g., the pixel electrode PE of FIG. 3) disposed on the data conductive layer SDL through a contact hole. Accordingly, a light emitting element (e.g., the light emitting element LED of FIGS. 2 and 3) and the first pixel circuit PC1 (or the second pixel circuit PC2) may be electrically connected through the anode connection pattern layer ACP.

The anode connection pattern layer ACP may be disposed in each of the first pixel circuit PC1 and the second pixel circuit PC2. The anode connection pattern layer ACP disposed in the first pixel circuit PC1 and the anode connection pattern layer ACP disposed in the second pixel circuit PC2 may be symmetrical to each other based on the imaginary symmetry line IML.

Referring again to FIGS. 13 and 14, a fifth insulating layer IL5 covering the data conductive layer SDL may be disposed on the fourth insulating layer IL4. For example, the fifth insulating layer IL5 may include an organic material such as phenol resin, acrylic resin, polyimide resin, polyamide resin, siloxane resin, epoxy resin, and the like. These may be used alone or in combination with each other. The fifth insulating layer IL5 may be referred to as an organic insulating layer.

Referring again to FIG. 3, as described above, the pixel defining layer PDL may be disposed on the circuit layer CL. For example, the pixel defining layer PDL may be disposed on the fifth insulating layer IL5. In an embodiment, no organic insulating layer other than the fifth insulating layer IL5 may be disposed between the fifth insulating layer IL5 and the pixel defining layer PDL. For example, only one organic insulating layer may be disposed between the fifth insulating layer IL5 and the pixel defining layer PDL.

Referring again to FIGS. 1, 2, 3, 4, 5, 6, 7, 8, 9, 10, 11, 12, 13, and 14, the display device DD according to embodiments may include the active layer AL, the first gate layer GL1 including the first gate electrode GE1 disposed on the active layer AL, the second gate layer GL2 disposed on the first gate layer GL1 and including the capacitor electrode CAE, the third gate layer GL3 disposed on the second gate layer GL2 and including the first power voltage line PVL1, and the data conductive layer SDL disposed on the third gate layer GL3. The capacitor electrode CAE may form the first capacitor C1 together with the first gate electrode GE1, and a part of the first power voltage line PVL1 may form the second capacitor C2 together with the capacitor electrode CAE. The third gate layer GL3 may include a low-resistance metal. For example, an additional data conductive layer may not be disposed between the data conductive layer SDL and the pixel electrode PE, and only one organic insulating layer may be disposed between the data conductive layer SDL and the pixel defining layer PDL. Accordingly, the display device DD may be implemented as a high-resolution rigid display device (e.g., rigid smartphone).

The disclosure may be applied to various display devices. For example, the disclosure may be applied to high-resolution smartphones, mobile phones, smart pads, smart watches, tablet PCs, vehicle navigation systems, televisions, computer monitors, laptops, and the like.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
an active layer disposed on a substrate;
a first gate layer disposed on the active layer and including a first gate electrode;
a second gate layer disposed on the first gate layer and including a capacitor electrode partially overlapping the first gate electrode, the capacitor electrode and the first gate electrode forming a first capacitor;
a third gate layer disposed on the second gate layer and including a first power voltage line partially overlapping the capacitor electrode and receiving a first power voltage, the first power voltage line and the capacitor electrode forming a second capacitor;
a data conductive layer disposed on the third gate layer; and
an inorganic insulating layer disposed between the third gate layer and the data conductive layer, and covering the third gate layer.

2. The display device of claim 1, wherein the inorganic insulating layer directly contacts the third gate layer.

3. The display device of claim 1, further comprising:
a light emitting element disposed on the data conductive layer and including an anode electrode;
an organic insulating layer disposed between the data conductive layer and the anode electrode; and
a pixel defining layer disposed on the organic insulating layer and covering an edge portion of the anode electrode,
wherein any organic insulating layer other than the organic insulating layer is not disposed between the organic insulating layer and the pixel defining layer.

4. The display device of claim 3, wherein
the light emitting element further includes a cathode electrode disposed on the anode electrode, the cathode electrode that receives a second power voltage, and
the first power voltage has a higher voltage level than the second power voltage.

5. The display device of claim 3, wherein the third gate layer further includes:
a first initialization voltage line that receives a first initialization voltage;
a second initialization voltage line that receives a second initialization voltage;
a first reference voltage line that receives a reference voltage;
a gate line that receives a gate signal; and
a bias voltage line that receives a bias voltage.

6. The display device of claim 5, wherein each of the first power voltage line, the gate line, the first and second initialization voltage lines, the first reference voltage line, and the bias voltage line extends in a first direction.

7. The display device of claim 6, wherein
the data conductive layer includes:
a second power voltage line that receives the first power voltage;
a second reference voltage line that receives the reference voltage; and
a data line that receives a data voltage,
the second power voltage line is connected to the first power voltage line, and
the second reference voltage line is connected to the first reference voltage line.

8. The display device of claim 7, wherein each of the second power voltage line, the second reference voltage line, and the data line extends in a second direction intersecting the first direction.

9. The display device of claim 1, wherein
the active layer includes a first active pattern layer and a second active pattern layer spaced apart from each other,
the first gate electrode partially overlaps the first active pattern layer, and the first gate electrode and a part of the first active pattern layer form a first transistor.

10. The display device of claim 9, wherein
the first gate layer further includes a second gate electrode spaced apart from the first gate electrode and partially overlapping the second active pattern layer, and
the second gate electrode and a part of the second active pattern layer form a second transistor.

11. The display device of claim 10, wherein
the third gate layer further includes a gate line spaced apart from the first power voltage line, the gate line that receives a gate signal, and
the gate line is connected to the second gate electrode through a contact hole.

12. The display device of claim 11, wherein
the date conductive layer includes a data line that receives a data voltage, and
the data line is connected to the second active pattern layer.

13. The display device of claim 1, wherein the substrate includes a glass substrate.

14. The display device of claim 1, wherein the third gate layer includes a low-resistance metal.

15. The display device of claim 1, wherein the third gate layer has a multi-layer structure including a titanium (Ti) layer, an aluminum (Al) layer, and a titanium (Ti) layer stacked with each other.

16. A display device comprising:
a first transistor that generates a driving current, the first transistor including:
a part of a first active pattern layer disposed on a substrate, and
a first gate electrode disposed on the first active pattern layer and partially overlapping the first active pattern layer;
a first capacitor including:
the first gate electrode, and
a capacitor electrode disposed on the first gate electrode and overlapping the first gate electrode;
a second capacitor including:
the capacitor electrode, and
a part of a first power voltage line disposed on the capacitor electrode and overlapping the capacitor electrode, the first power voltage line that receives a first power voltage;
a data conductive layer disposed on the first power voltage line and including an anode connection pattern layer;
an inorganic insulating layer disposed between the capacitor electrode and the data conductive layer, and covering the capacitor electrode; and
a light emitting element disposed on the data conductive layer and including an anode electrode connected to the anode connection pattern layer and a cathode electrode that receives a second power voltage different from the first power voltage.

17. The display device of claim 16, wherein the inorganic insulating layer directly contacts the first power voltage line.

18. The display device of claim 16, further comprising:
an organic insulating layer disposed between the data conductive layer and the anode electrode; and
a pixel defining layer disposed on the organic insulating layer and covering an edge portion of the anode electrode,
wherein any organic insulating layer other than the organic insulating layer is not disposed between the organic insulating layer and the pixel defining layer.

19. The display device of claim 16, further comprising:
a first initialization voltage line that receives a first initialization voltage;
a second initialization voltage line that receives a second initialization voltage;
a first reference voltage line that receives a reference voltage;
a gate line that receives a gate signal; and
a bias voltage line that receives a bias voltage,
wherein the first power voltage line, the gate line, the first and second initialization voltage lines, the first reference voltage line, and the bias voltage line are formed as a same layer.

20. The display device of claim 19, wherein each of the first power voltage line, the gate line, the first and second initialization voltage lines, the first reference voltage line, and the bias voltage line extends in a first direction.

21. The display device of claim 20, wherein
the data conductive layer includes:
a second power voltage line that receives the first power voltage;
a second reference voltage line that receives the reference voltage; and
a data line that receives a data voltage,
the second power voltage line is connected to the first power voltage line, and
the second reference voltage line is connected to the first reference voltage line.

22. The display device of claim 21, wherein each of the second power voltage line, the second reference voltage line, and the data line extends in a second direction intersecting the first direction.

23. The display device of claim 16, further comprising:
a second transistor including a part of a second active pattern layer and a second gate electrode partially overlapping the second active pattern layer, wherein
the second active pattern layer and the first active pattern layer are formed as a same layer, and
the second gate electrode and the first gate electrode are formed as a same layer.

24. The display device of claim 23, further comprising:
a gate line that receives a gate signal, wherein
the gate line and the first power voltage line are formed as a same layer, and
the gate line is connected to the second gate electrode through a contact hole.

25. The display device of claim 24, wherein
the date conductive layer includes a data line that receives a data voltage, and
the data line is connected to the second active pattern layer.
